(19) United States
(12) Patent Application Publication
(10) Pub. No.: US 2026/0157122 A1
(43) Pub. Date: Jun. 4, 2026

(54) RRAM DEVICES AND METHODS OF MANUFACTURING AND OPERATING THEREOF

(71) Applicants: Tokyo Electron Limited, Tokyo (JP); International Business Machines Corporation, Armonk, NY (US)

(72) Inventors: Steven Consiglio, Albany, NY (US); Kenichi Imakita, Albany, NY (US); Takaaki Tsunomura, Tokyo (JP); Paul Jamison, Hopewell Junction, NY (US); Takashi Ando, Yorktown Heights, NY (US); Kevin Brew, Yorktown Heights, NY (US)

(21) Appl. No.: 18/968,949

(22) Filed: Dec. 4, 2024

(51) Int. Cl. H10N 70/00; H10B 63/00; H10N 70/20

(52) U.S. Cl. CPC H10N 70/8833; H10B 63/30; H10B 63/84; H10N 70/023; H10N 70/026; H10N 70/063; H10N 70/24; H10N 70/841

(57) ABSTRACT

A resistive memory device is provided that includes a first metal line oriented along a first direction. A first electrode is coupled to and disposed over the first metal line. A first metal oxide layer is disposed over the first electrode. A first oxygen reservoir layer is disposed over the first metal oxide layer, followed by a second metal oxide layer over the first oxygen reservoir layer. A second oxygen reservoir layer is disposed over the second metal oxide layer. A second electrode is disposed over the second oxygen reservoir layer, and a second metal line, oriented along a second direction, is coupled to and disposed over the second electrode. These components together form part of the resistive memory device.

### TECHNICAL FIELD

This application relates generally to electronic devices, and, in particular embodiments, to resistive random-access memory (RRAM) devices and methods for manufacturing and operating the same.

### BACKGROUND

Filamentary switching in metal oxide-based resistive random-access memory (RRAM) involves the formation and disruption of conducting filaments within a resistive switching layer. These filaments predominantly comprise oxygen vacancies, which are localized regions where oxygen atoms are absent. The oxygen vacancies enhance the material's electrical conductivity, allowing for the storage and modulation of data within the memory device. When an external voltage is applied, these filaments can form or rupture, thereby altering the device's resistive state. For analog computing, the ability to form and rupture multiple filaments within the resistive switching layer can improve analog properties. This multifilament approach addresses issues associated with abrupt changes in resistance that occur when a single filament forms or ruptures.

### SUMMARY

In accordance with one aspect of the present invention, a resistive memory is provided comprising a first metal line oriented along a first direction, a first electrode coupled to and disposed over the first metal line, a first metal oxide layer disposed over the first electrode, a first oxygen reservoir layer disposed over the first metal oxide layer, a second metal oxide layer disposed over the first oxygen reservoir layer, a second oxygen reservoir layer disposed over the second metal oxide layer, a second electrode disposed over the second oxygen reservoir layer, and a second metal line coupled to and disposed over the second electrode and oriented along a second direction. The first and second electrodes, first and second oxygen reservoir layers, and first and second metal oxide layers form part of a resistive memory device.

In accordance with another aspect of the present invention, a resistive memory is provided comprising a first metal line oriented along a first direction, a first electrode coupled to and disposed over the first metal line, a first metal oxide layer disposed over the first electrode, a first oxygen reservoir layer disposed over the first metal oxide layer, a second metal oxide layer disposed over the first oxygen reservoir layer, a first metal layer disposed over the second metal oxide layer, a second electrode disposed over the first metal layer, and a second metal line coupled to and disposed over the second electrode and oriented along a second direction. The first and second electrodes, first and second metal oxide layers, first oxygen reservoir layer, and first metal layer form part of a resistive memory device.

In accordance with yet another aspect of the present invention, a method of forming a resistive memory is provided comprising forming a first metal line disposed over a substrate and oriented along a first direction, forming a first electrode disposed over the first metal line, forming a first metal oxide layer disposed over the first electrode, forming a first oxygen reservoir layer disposed over the first metal oxide layer, forming a second metal oxide layer disposed over the first oxygen reservoir layer, forming a second oxygen reservoir layer disposed over the second metal oxide layer, forming a second electrode disposed over the second oxygen reservoir layer, and forming a second metal line disposed over the second electrode and oriented along a second direction orthogonal to the first direction.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A and FIG. 1B illustrate a three-dimensional view of a resistive memory array and a cross-sectional view of a resistive memory, in accordance with an embodiment;

FIGS. 2A-2D illustrate cross-sectional views of resistive memory of different variations in layer configuration, in accordance with various embodiments;

FIGS. 3A-3D illustrate the responses of resistive memory device to external electrical signal inputs, in accordance with various embodiments;

FIGS. 4A-4H illustrate cross-sectional views of the formation of a resistive memory, in accordance with an embodiment;

FIGS. 5A-5D illustrate top-down views of the formation of a resistive memory, in accordance with an embodiment;

FIG. 6 illustrates a flow chart of an in-situ fabrication process to form a super-lattice structure within a resistive random-access memory (RRAM) device, in accordance with an embodiment;

FIG. 7 illustrates a flow chart of an ex-situ fabrication process to form a super-lattice structure within a resistive random-access memory (RRAM) device, in accordance with an embodiment.

### DETAILED DESCRIPTION OF ILLUSTRATIVE EMBODIMENTS

RRAM devices typically transition from a resistive state to a conductive state with minimal resistance at a specific voltage resulting in a binary response. In other words, they have a single state that can be turned ON or OFF upon reaching above or below a specific voltage.

Analog applications may benefit from a more linear response with multiple states. However, conventional RRAM devices cannot exhibit such a behavior. In fact, they abruptly transition from a conductive ON state to a resistive OFF state due to the rapid formation of a filament at the programming voltage or a rapid rupture at the erase voltage.

Increasing the number of conductance states while avoiding such instantaneous or rapid filament formation and rupture may be particularly advantageous for many analog applications as well as for artificial intelligence (AI) and machine learning (ML) applications, which demand high precision and tunability in training processes. By achieving a wider range of tunable conductance states, the RRAM devices can better mimic synaptic weights and other features of biological neural networks, thereby improving the efficiency and performance of AI and ML algorithms.

Embodiments of this application describe structures and methods to form RRAM device with multiple conductance states that enable a more gradual transition from a resistive state to multiple conductive states. Such transitions are enabled by the formation of potentially multiple conductive filaments as will be described in more detail below.

In various embodiments, this disclosure describes RRAM devices featuring a super-lattice structure comprising a plurality of alternating resistive switching layers, oxygen reservoir layers, and metal layers. The super-lattice structure may leverage multiple interfaces formed between resistive switching layers and oxygen reservoir layers, or between resistive switching layers and metal layers to achieve multiple filament formation and rupture points.

As will be further described in various embodiments, the super-lattice structure may include a layer stack comprising alternating resistive switching layers and oxygen reservoir layers. The oxygen reservoir layer may comprise a metal oxide layer and provide a source of oxygen atoms to the resistive switching layers. Thus, the oxygen reservoir layer may stabilize filaments through a controlled introduction of oxygen ions into the resistive switching layer.

In addition, in various embodiments, the super-lattice structure may not introduce additional layers such as thermal or electro-thermal modulation layers, to achieve multiple filament formation. By not introducing additional layers, embodiments may maintain a thickness comparable to conventional bi-layer structures, leading to a high memory storage density at low production cost. By limiting the thickness of each individual resistive switching layer, the new structure may also provide enhanced control over crystallinity and grain size, contributing to better device performance and reliability.

Furthermore, the super-lattice structure may be fabricated in-situ or ex-situ with conventional thin film processing techniques such as physical vapor deposition (PVD) and atomic layer deposition (ALD), as well as conventional fab-friendly metal oxides such as hafnium oxides, zirconium oxides, and tungsten oxides. This compatibility allows for facile integration into existing fabrication processes for low-cost and scale-up production.

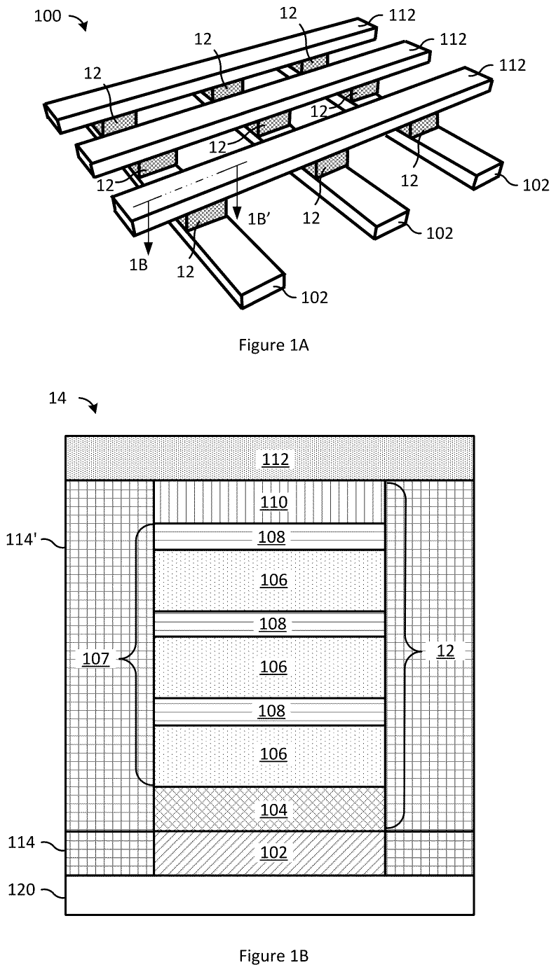

FIGS. 1A-1B illustrate a resistive memory in accordance with an embodiment, wherein FIG. 1A illustrates a three-dimensional view of a resistive memory array and FIG. 1B illustrates a cross sectional view of a resistive memory. In particular, FIG. 1B depicts the cross-sectional view along a line 1B-1B′ indicated in FIG. 1A.

FIG. 1A illustrates a three-dimensional view of a resistive memory array 100 comprising a plurality of resistive memories 14.

The disclosed structure may comprise a plurality of first metal lines (or bit lines) 102 and second metal lines (or word lines) 112 that couple to a plurality of resistive memory devices 12 forming the resistive memory 14. The resistive memory devices 12 may be arranged in a crossbar array configuration, where each device may be coupled to a first metal line 102 and a second metal line 112.

The first and the second metal lines 102 and 112 may comprise electrically conductive materials such as metals, comprising copper, aluminum, titanium, gold, silver, tungsten, niobium, molybdenum, platinum, tantalum, zirconium, hafnium, lanthanum, ruthenium, palladium, or cobalt. The first metal lines 102 may be oriented along a first direction like a horizontal direction, and may be used to select the rows of the resistive memory array, while the second metal lines 112 may be oriented along a second direction that may be orthogonal to the first direction and be used to select the columns. This configuration allows for precise addressing and efficient read/write operations of selective resistive memory devices 12 within the resistive memory array 100, enabling high-density and high-performance memory storage.

The structure of one of the resistive memory devices 12 will be described below in various embodiments. While crossbar array memory architecture is illustrated, embodiments of the resistive memory devices 12 may be used in any other memory design.

FIG. 1B illustrates a cross-sectional view of a resistive memory 14 along a line 1B-1B′ indicated in FIG. 1A. In some embodiments, the resistive memory 14 may comprise a first metal line 102 disposed over a substrate 120, a resistive memory device 12 disposed over the first metal line 102, and a second metal line 112 disposed over the resistive memory device 12.

A first insulating layer 114 and the second insulating layer 114′ may be disposed over the substrate 120 to avoid direct contact between the first metal line 102 and the second metal line 112. Additionally, these insulating layers may isolate different resistive memory devices 12, thereby preventing electrical interference and ensuring reliable operation. This arrangement may preserve the integrity of individual metal lines and mitigate cross-talk or short-circuiting between adjacent memory devices, thus enhancing overall device performance and reliability. The material for the first insulating layer 114 and the second insulating layer 114′ may comprise silicon dioxide, silicon nitride, aluminum oxide, hafnium oxide, tantalum pentoxide, boron nitride, polyimide, low-k dielectrics, silicon carbide, or phosphosilicate glass.

The substrate 120 may be a bulk substrate such as a blank silicon wafer, a silicon-on-insulator (SOI) wafer, or any of various other semiconductor substrates. The substrate 120 may also be coated or layered with any number of additional materials, including compound semiconductors, metal or metal oxides, or metal nitrides. The substrate 120 may include any material portion or structure of a device, particularly a semiconductor or other electronics device.

The resistive memory device 12 may comprise a stack of layers. It may comprise a first electrode 104, which may serve as a bottom electrode, being disposed over the first metal line 102. A first metal oxide layer 106, which may serve as a first resistive switching layer, may be disposed over the first electrode 104. A first oxygen reservoir layer 108 may be disposed over the first metal oxide layer 106. A second metal oxide layer 106, which may serve as a second resistive switching layer, may be disposed over the first oxygen reservoir layer 108. A second oxygen reservoir layer 108 may be disposed over the second metal oxide layer 106, following which a repeating stacks of metal oxide layers 106 and oxygen reservoir layers 108 may be alternatively disposed over each other. A second electrode 110 may be disposed over the last disposed oxygen reservoir layer 108 and serve as a top electrode. The oxygen reservoir layer 108 may comprise electrically conductive materials. A super-lattice structure 107 may be formed by a plurality of metal oxide layers 106 and oxygen reservoir layers 108 alternatively disposed over each other.

The first electrode 104 and the second electrode 110 may comprise any suitable electrically conductive material, including metals such as cobalt, nickel, copper, aluminum, silver, gold, platinum, iridium, ruthenium, or tungsten; conductive nitrides such as titanium nitride or tantalum nitride; or conductive oxides such as iridium(IV) oxide, ruthenium(IV) oxide, lanthanum strontium cobalt oxide (LSCO), strontium ruthenium oxide (SRO), or lanthanum-doped SRO, according to various embodiments.

The metal oxide layer 106, in some embodiments, may comprise hafnium oxide (HfOₓ, 0≤x≤2), zirconium oxide (ZrOₓ, 0≤x≤2), hafnium zirconium oxide (HfₓZr₁₋ₓO_{z}, 0≤x≤1, 0≤z≤2), tantalum oxide (TaOₓ, 0≤x≤2.5) or titanium oxide (TiOₓ, 0≤x≤2). Metal oxides such as hafnium oxide, zirconium oxide, and hafnium zirconium oxide have several advantages to compose the metal oxide layer 106. These metal oxides exhibit large band gap, high thermal stability, and high compatibility with existing semiconductor manufacturing processes. These materials also have high chemical stability that reduces the likelihood of unwanted side reactions, thereby providing stable performance under aggressive cycling conditions. The metal oxide layer 106 may comprise oxygen vacancies that may migrate between adjacent lattice positions under an electric field. The migration of the oxygen vacancies may result in the formation or rupture of a conducting filament formed within the metal oxide layer 106.

The oxygen reservoir layer 108, in some embodiments, may be a multivalent metal oxide with high affinity to oxygen and comprise tungsten oxide (WOₓ, 0≤x≤3). The high affinity to oxygen improves the ability of the metal oxide to release and absorb oxygen ions as needed, maintaining an optimal concentration of oxygen vacancies for reliable device performance. The physical mechanisms are related to oxygen exchange between the conductive filament in the resistive switching metal oxide layer and the oxygen reservoir layer involving interface oxygen exchange, drift through grain boundaries and defects, and valence change in the oxygen reservoir layer. Metal oxides such as tungsten oxide (WOₓ, 0≤x≤3) show several advantages to compose the oxygen reservoir layer 108. Tungsten oxide is chemically stable and can maintain its structure while providing oxygen ions efficiently. This stability ensures that the oxygen reservoir layer remains effective over many switching cycles. Moreover, it can withstand high temperatures during the fabrication of memory devices without decomposing or losing its functional properties.

In some embodiments, the oxygen reservoir layer 108 may be disposed adjacent to the metal oxide layer 106 to regulate the availability of oxygen vacancies and provide a dynamic oxygen source. This arrangement may facilitate the migration of oxygen vacancies by either releasing or absorbing oxygen vacancies from the metal oxide layer 106 as needed. During the formation of conducting filaments in the metal oxide layer 106, oxygen vacancies may migrate and aggregate to form these filaments. The oxygen reservoir layer 108 may release oxygen when necessary to maintain an optimal concentration of oxygen vacancies in the metal oxide layer 106, thereby stabilizing the conductive pathways. This controlled release and absorption of oxygen ions help maintain consistent switching behavior, improving both the reliability and endurance of the RRAM device.

Oxygen management through an oxygen reservoir layer exhibits multiple advantages over other approaches such as using an oxygen scavenging layer, which may comprise a titanium (Ti) layer and a titanium nitride (TiN) layer. The need for specific materials like Ti/TiN may limit material compatibility and processing flexibility, requiring additional steps to ensure these layers integrate well with other materials in the device stack. Moreover, Ti/TiN layers may introduce variability in the resistive switching characteristics due to inconsistent scavenging efficiency. This may lead to unreliable switching behavior and negatively impact the device reliability over repeated cycles.

The super-lattice structure 107 retains the aforementioned benefits of incorporating an oxygen reservoir layer and provides additional advantages, particularly in analog computing applications. Unlike conventional bi-layer structures composing one single oxygen reservoir layer and one single resistive switching layer with limited conductance states, the super-lattice structure may enable the formation of multiple, stable conducting filaments at various points within the metal oxide layers, resulting in more conductance states and wider conductance range. These conductance states may apply to emulate synaptic weights to improve the performance of neuromorphic systems, thereby improving the performance and efficiency of AI and ML algorithms.

Moreover, the super-lattice structure 107 may not require additional layers such as thermal enhancement layers (TEL), to achieve multiple filament formations. These layers are employed to manage temperature distribution by confining heat within the resistive switching layer. The thermal effect leads to multiple weak filaments formation, for example, in a HfOₓ/TEL structure, that improves analog behavior. However, incorporating these additional layers adds extra thickness to the device, for example, the TEL layer may reach 60 nm, which reduces memory storage density leading to higher production cost. In contrast, without these additional layers, the super-lattice structure 107 has a simplified device design with higher storage density, fewer manufacturing steps and lower production cost.

In some embodiments, the super-lattice structure 107 may maintain a thickness comparable to conventional bi-layer structures in the range of 2 nm to 20 nm. Moreover, by limiting the film thickness of each individual metal oxide layer 106, the new structure may provide enhanced control over its crystallinity and grain size. Thinner layers may reduce the likelihood of defects and irregularities that can occur in thicker films, leading to more uniform material properties of the metal oxide layer 106. In some embodiments, the thickness of metal oxide layer 106 may range from 1 nm to 10 nm, which may provide sufficient thickness for uniform formation and rupture of conducting filaments, resulting in reliable switching and good data retention. The layer may be thin enough to induce resistance switching under low voltages, leading to low power consumption. In some embodiments, the thickness of oxygen reservoir layer 108 may comprise 1 nm to 10 nm, providing reliable oxygen vacancy control, low power operation, and robust data retention.

Additionally, the composition, thickness, and quantity of the metal oxide layers 106 and the oxygen reservoir layers 108 may be precisely adjusted to control properties such as conducting filament diameters, conductance levels, and other material characteristics. For example, reducing the thickness of the metal oxide layer 106 may increase the layer conductance, resulting in different device conductance state. In another example, altering the composition of an oxygen reservoir layer 108 to increase the oxygen vacancy concentration can enhance conductivity. In another example, increasing the quantity of metal oxide layers 106 and oxygen reservoir layers 108 may provide more interfaces for conducting filament formation and rupture, thereby enabling additional conductance states. These tunable parameters enable high flexibility in optimizing device performance to meet specific performance requirements, thereby improving overall device functionality and commercial viability.

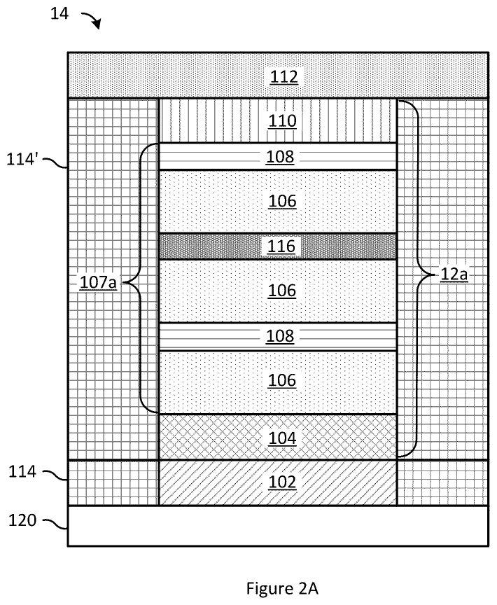

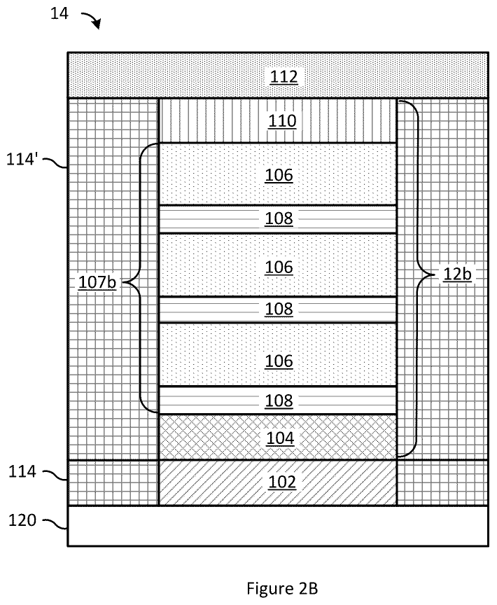

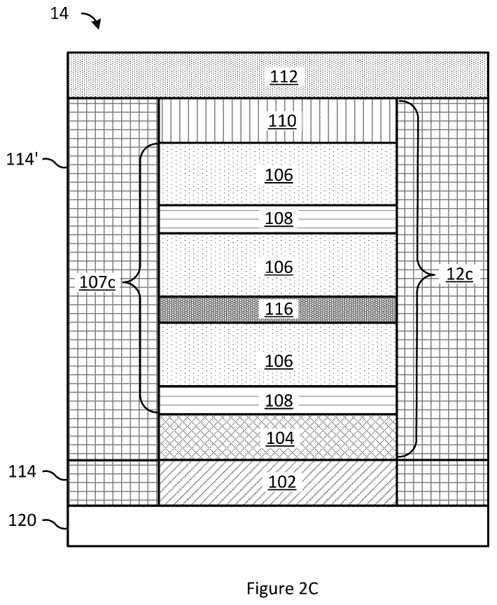

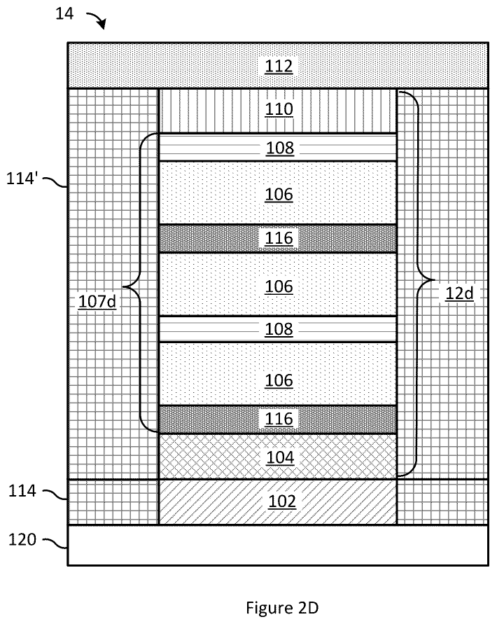

FIGS. 2A-2D illustrate cross-sectional views of resistive memory of different variations in layer configuration, in accordance with various embodiments.

In one variation, as illustrated in FIG. 2A, one or more of the oxygen reservoir layers 108 may be substituted with a metal layer 116. The super-lattice structure 107a may comprise a plurality of metal oxide layers 106, oxygen reservoir layers 108 and metal layers 116. The metal layer 116 may comprise metallic materials with high electrical conductivities such as tungsten, copper, aluminum, titanium, gold, platinum, zirconium, or hafnium. The introduction of metal layers 116 within the super-lattice structure 107a may enhance device conductivity, thereby improving memory device switching speed. Moreover, the metal layers 116 may improve device thermal conductivity, which helps dissipate heat more effectively during operation, thereby enhancing the endurance of the memory device.

In another variation, as illustrated in FIG. 2B, the resistive memory device 12b comprises an alternative layer sequence. In some embodiments, the resistive memory 14 may comprise the first metal line 102 disposed over the substrate 120, the resistive memory device 12b disposed over the first metal line 102, and the second metal line 112 disposed over the resistive memory device 12b. The first insulating layer 114 and the second insulating layer 114′ may be disposed over the substrate 120 to prevent direct contact between the first metal line 102 and the second metal line 112. These insulating layers may also isolate different resistive memory devices 12b to prevent electrical interference. The resistive memory 14 may respectively comprise the materials, structures, and/or other components described above with reference to corresponding parts of FIG. 1B.

The resistive memory device 12b, in some embodiments, may comprise a stack of layers. It may comprise a first electrode 104 which may serve as the bottom electrode, being disposed over the first metal line 102. The first oxygen reservoir layer 108 may be disposed over the first electrode 104, and the first metal oxide layer 106 may be disposed over the first oxygen reservoir layer 108. The second oxygen reservoir layer 108 may be disposed over the first metal oxide layer 106. The second metal oxide layer 106 may be disposed over the second oxygen reservoir layer 108, following which the repeating stacks of metal oxide layers 106 and oxygen reservoir layers 108 may be alternatively disposed over each other. The second electrode 110 which may serve as the top electrode, may be disposed over the last disposed metal oxide layer 106. Each oxygen reservoir layer 108 may comprise electrically conductive materials. The super-lattice structure 107b may be different from super-lattice structure 107 in the sequence of disposing metal oxide layers 106 and oxygen reservoir layers 108. The resistive memory device 12b may respectively comprise the materials, structures, and/or other components described above with reference to corresponding parts of FIG. 1B. This variation in layer sequence may contribute to a better flexibility in device design and integration with additional functional layers, such as barrier layers or conductive interlayers, to further enhance device performance by meeting specific requirements.

With reference to FIG. 2C, another variation of the resistive memory 14 is illustrated. The resistive memory 14 may comprise the first metal line 102, the second metal line 112 and the resistive memory device 12c disposed between the first and second metal lines 102 and 112. The resistive memory device 12c may comprise the super-lattice structure 107c comprising a stack of layers. The super-lattice structure 107c may comprise the first oxygen reservoir layer 108 being disposed over the first electrode 104. The first metal oxide layer 106 may be disposed over the first oxygen reservoir layer 108. The first metal layer 116 may be disposed over the first metal oxide layer 106. The second metal oxide layer 106 may be disposed over the first metal layer 116. The second oxygen reservoir layer 108 may be disposed over the second metal oxide layer 106. The third metal oxide layer 106 may be disposed over the second oxygen reservoir layer 108. In some embodiments, the super-lattice structure 107c may comprise additional metal oxide layers 106 and oxygen reservoir layers 108 alternatively disposed over each other. In some embodiments, the super-lattice structure 107c may comprise additional metal oxide layers 106 and metal layers 116 alternatively disposed over each other. The metal layer 116 may comprise the materials, structures, and/or other components described with reference to the metal layer 116 of FIG. 2A. The addition of metal layers 116 may improve the switching speed and cycling endurance of the RRAM device by increasing the electrical and thermal conductivities. The second electrode 110 may be disposed over the super-lattice structure 107c. The resistive memory 14 may respectively comprise the materials, structures, and/or other components described above with reference to corresponding parts of FIG. 1B.

FIG. 2D illustrates another variation of the resistive memory 14 comprising the first metal line 102, the second metal line 112 and the resistive memory device 12d. The resistive memory device 12d, in some embodiments, may comprise the first electrode 104 (serving as the bottom electrode) disposed over the first metal line 102. The super-lattice structure 107d within the resistive memory device 12d may comprise a stack of layers. It may comprise the first metal layer 116 being disposed over the first electrode 104. The first metal oxide layer 106 may be disposed over the first metal layer 116. The first oxygen reservoir layer 108 may be disposed over the first metal oxide layer 106. The second metal oxide layer 106 may be disposed over the first oxygen reservoir layer 108. The second metal layer 116 may be disposed over the second metal oxide layer 106. The third metal oxide layer 106 may be disposed over the second metal layer 116. The second oxygen reservoir layer 108 may be disposed over the third metal oxide layer 106. In some embodiments, the super-lattice structure 107d may comprise additional metal oxide layers 106 and oxygen reservoir layers 108 alternatively disposed over each other. In some embodiments, the super-lattice structure 107d may comprise additional metal oxide layers 106 and metal layers 116 alternatively disposed over each other. The second electrode 110 may be disposed over the super-lattice structure 107d. The metal layer 116 may comprise the materials, structures, and/or other components described with reference to the metal layer 116 of FIG. 2A. The resistive memory 14 may respectively comprise the materials, structures, and/or other components described above with reference to corresponding parts of FIG. 1B.

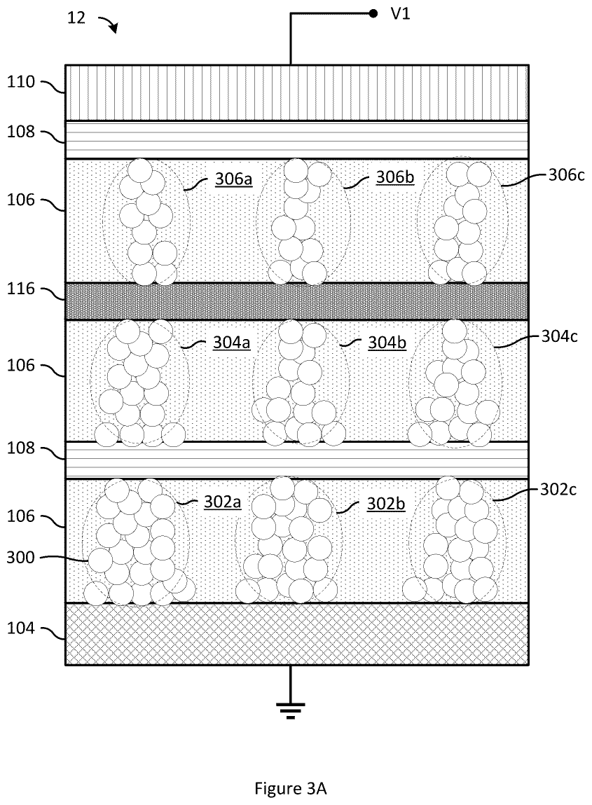

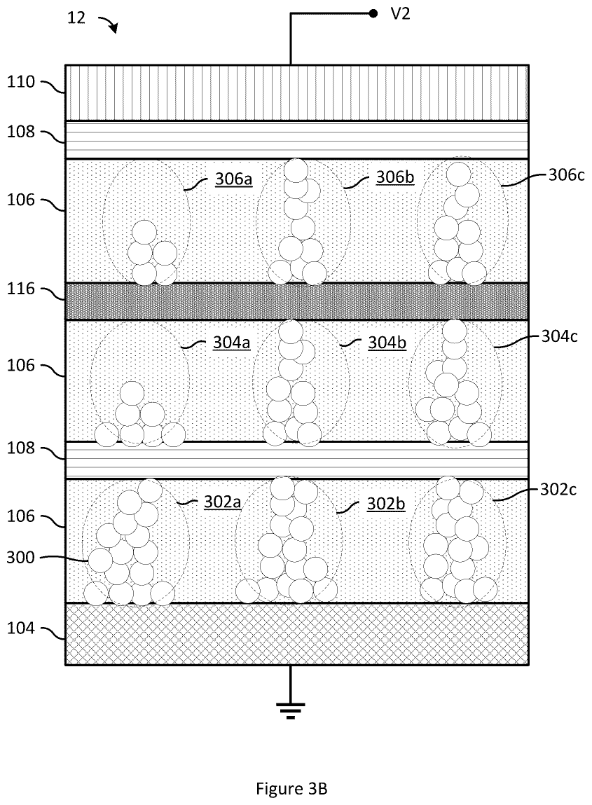

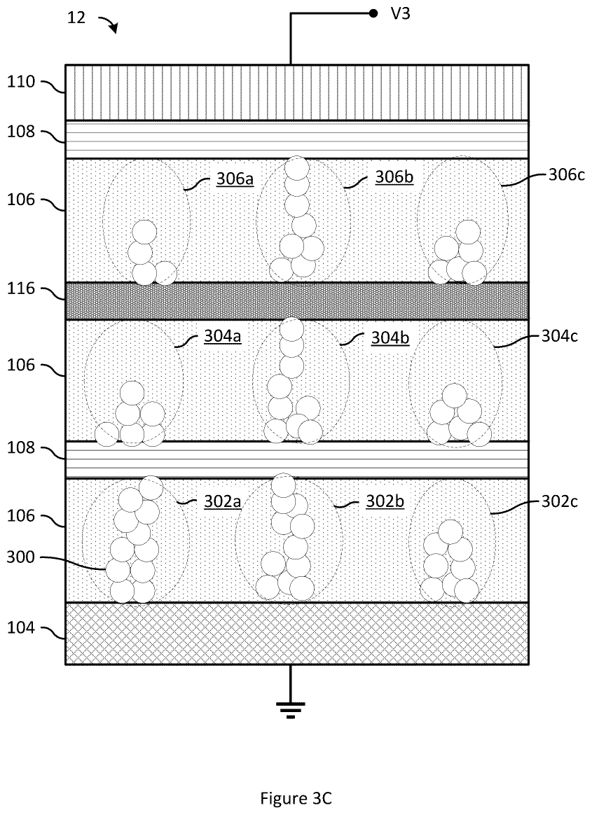

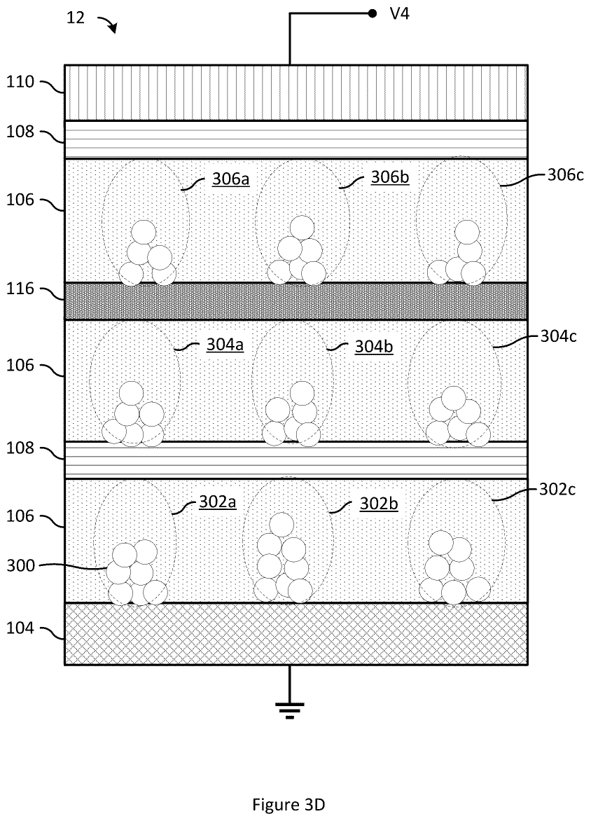

FIGS. 3A-3D illustrate responses of oxygen vacancies in the resistive memory device 12 to applied electrical signals, according to various embodiments. An electrical signal, such as voltage, may be applied to the resistive memory device 12 to change the resistance of the resistive memory device 12.

In one embodiment, FIG. 3A illustrates that a forward (positive) voltage V1 may be applied to the second electrode 110 while the first electrode 104 is grounded. The forward voltage V1 may generate an electric field within the device 12, driving the positively charged oxygen vacancies 300 towards the grounded electrode (or the oxygen ions towards the positive electrode) resulting in a network of oxygen vacancies, referred to as oxygen vacancy conducting filaments 302a, 302b, 302c, 304a, 304b, 304c, 306a, 306b, and 306c. The conducting filaments thus formed are highly defective states and provide a path for charge transfer.

These filaments may comprise different diameters, each contributing to a distinct conductance in the respective metal oxide layers 106. The thickness and composition of each metal oxide layer 106 may affect the filament formation and respective diameters. For example, the filament 302a may have larger diameter than the filament 304a and filament 306a, leading to higher conductance of the corresponding metal oxide layer. The formation of multiple conducting filaments may electrically connect the oxygen reservoir layers 108 and metal layers 116, thereby connecting the first electrode 104 and the second electrode 110. The connection may transition the resistive memory device 12 to an ON state characterized by a high conductance and a high output current.

Referencing FIG. 3B, the forward voltage V1 may be adjusted to a lower value V2 (where V2<V1). Under this condition, the accumulation of oxygen vacancies in each metal oxide layer 106 may reduce but vary among different layers. For example, the oxygen vacancy conducting filaments 304a and 306a may rupture, while filaments 302a, 302b, 302c, 304b, 304c, 306b, and 306c may exhibit reduced diameters without rupturing. Consequently, each metal oxide layer 106 exhibits different conductance, and the quantity of conducting filaments that electrically connect the first electrode 104 and the second electrode 110 may reduce, resulting in a lower overall conductance of the resistive memory device 12 and a corresponding lower output current from the device. The device remains in an ON state but with a reduced output current.

With reference to FIG. 3C, when a further reduced forward voltage V3 (where V3<V2) may be applied, the accumulation of oxygen vacancies may continue to reduce but remain different across each metal oxide layer 106. For example, more oxygen vacancy filaments may rupture such as 302c, 304a, 304c, 306a, and 306c, while filaments 302a, 302b, 304b, and 306b may only reduce in diameter without rupturing. This leads to further variation in the conductance of each metal oxide layer 106 and the quantity of conducting filaments that electrically connect the first electrode 104 and the second electrode 110 may be further reduced. Consequently, the overall conductance of resistive memory device 12 may be further reduced, resulting in a further decreased output current. The device may stay in an ON state but with a differently reduced output current.

FIG. 3D illustrates that applying a reverse voltage V4 may cause the rupture of oxygen vacancy conducting filaments 302a, 302b, 302c, 304a, 304b, 304c, 306a, 306b, and 306c, leading to an OFF state of the resistive memory device 12, characterized by a substantially reduced or zero output current. Between voltages V1 and V4, there may be multiple intermediate voltages capable of triggering varying filament formations, characterized by different levels of oxygen vacancy accumulation and filament diameters, as well as ruptures within each metal oxide layer 106. The multiple filament states enabled by the super-lattice structure 107 may allow for numerous possible conductance states and wider conductance range from the RRAM device, which may improve the precision of data processing in analog computing applications. In contrast, conventional bi-layer structures have limited states and abrupt conductance changes due to fewer discrete conductance states, limiting their application in analog computing.

In some embodiments, operating the resistive memory device 12 may involve applying different voltages between the first electrode 104 and the second electrode 110 to induce changes in the conductance state of each metal oxide layer 106, which subsequently affects the output current. These voltages may be used to create multiple conductance states by precisely controlling the formation and rupture of oxygen vacancy filaments in each metal oxide layer 106. When a sufficient forward bias is applied, oxygen vacancies in the metal oxide layers may aggregate to form one or more conducting filaments, transitioning the device from low-conductance states (LCS) to high-conductance states (HCS). This transition is characterized by an increase in output current. By varying the magnitude of the applied forward bias, different levels of vacancy aggregation and filament formation may be achieved, resulting in multiple intermediate conductance states between LCS and HCS, enhancing the device's versatility for analog computing application. Conversely, applying a reverse bias may cause the conducting filaments to rupture, reverting the device back to various low-conductance states. This results in a decrease in output current and allows for fine-tuned control over erase operations or reduction in synaptic strength in analog computing scenarios. The ability to finely tune these conductance states through precise control of applied voltages enhances the performance of the RRAM device in analog applications. Varying resistance levels may be utilized for arithmetic operations, signal processing, and emulating neural network behaviors with higher precision.

In some embodiments, the disclosed resistive memory device 12 may integrate with a transistor to form an 1T-1R memory cell comprising a single transistor (1T) and a single memory device (1R) connected in series. The transistor may serve as an access device, controlling the read and write operations to the resistive memory device 12. This integration may enhance the precise control of current flowing through the resistive memory device 12, thereby improving the reliability and performance of the memory cell. In some embodiments, the transistor may comprise metal-oxide-semiconductor field-effect transistors (MOSFETs), thin-film transistors (TFTs), organic field-effect transistors (OFETs), Indium-Gallium-Zinc-Oxide transistors (IGZO FETs), or two-dimensional material-based field-effect transistors (2D FETs) such as molybdenum disulfide (MoS₂) field-effect transistors (FETs). The formation of the 1T-1R memory cell may provide a scalable solution for high-density memory applications, offering advantages in terms of reduced power consumption, improved switching speed, and enhanced data retention.

In some embodiments of operating the 1T-1R memory cell, the single transistor (1T) and the single resistive memory device (1R) may be connected in series, wherein the transistor may serve as an access device controlling the read and write operations of the resistive memory device 12. A control signal may be applied to the gate terminal of the transistor, allowing the selection and current flow through the resistive memory device 12. During write operations, a forward voltage may create an electric field that induces the migration and aggregation of oxygen vacancies within each metal oxide layer 106 of the super-lattice structure 107, forming one or more conducting filaments and transitioning the device from low-conductance states to high-conductance states. This forward bias may be varied to create multiple intermediate conductance states, enhancing the device's versatility for analog computation by enabling precise adjustment of conductance levels. Conversely, applying a reverse voltage may cause these filaments to rupture, reverting the device back to various low-conductance states. The transistor may precisely modulate current flow during these operations to prevent damage and minimize power consumption. During read operations, a lower voltage may be applied, and the transistor may connect the resistive memory device 12 to the read circuitry; the resulting current level corresponds to the conductance state of the RRAM device, enabling accurate and non-destructive readout. This 1T-1R configuration may enhance switching speeds, reduce power consumption, improve data retention, and increase endurance.

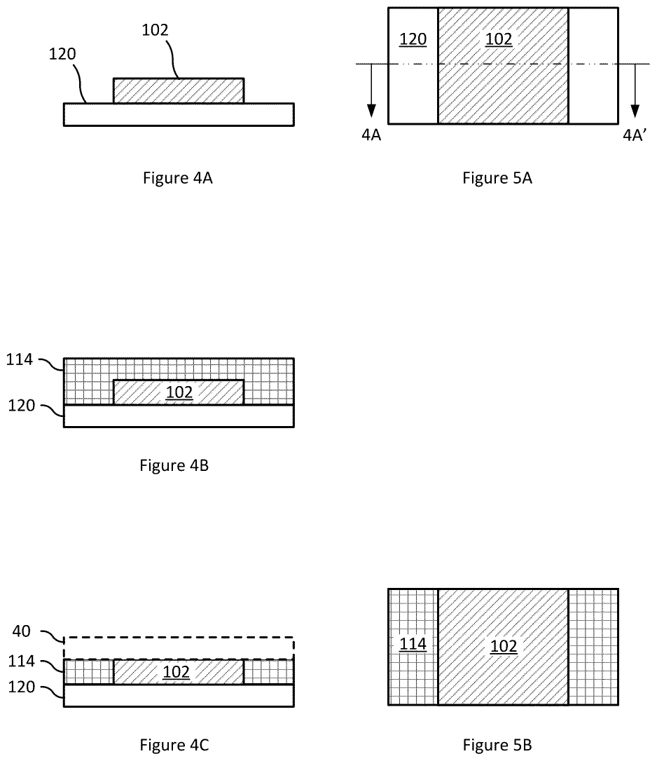

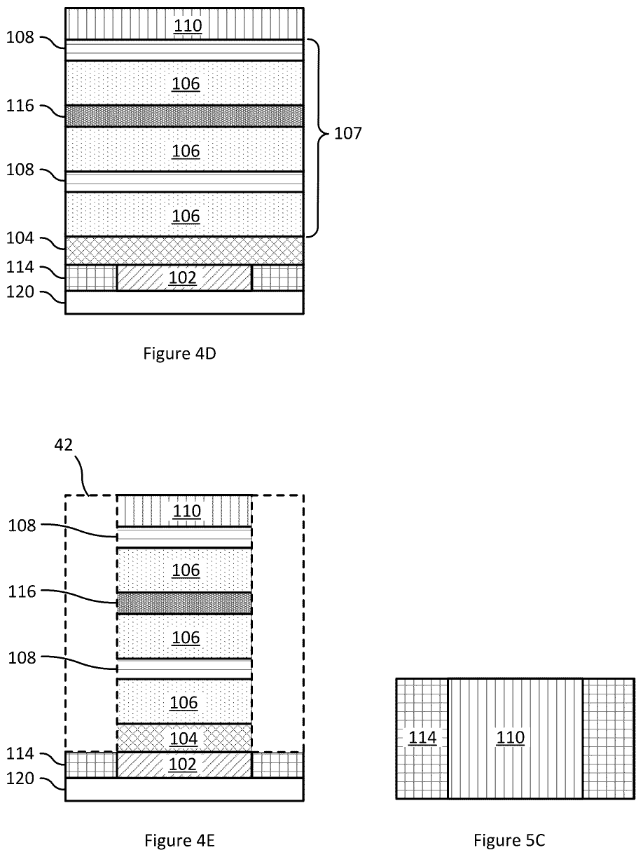

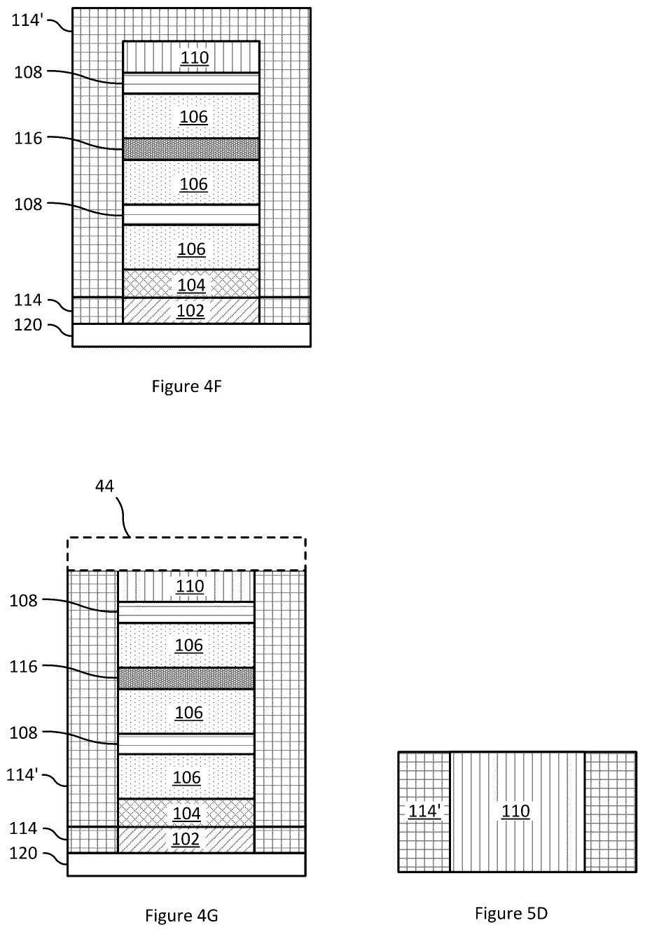

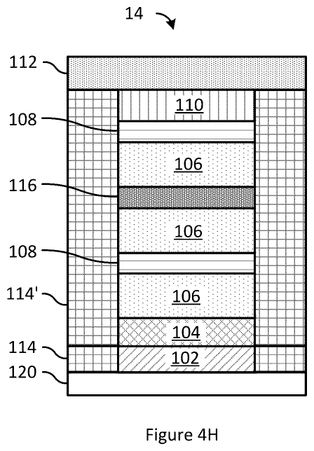

FIGS. 4A-4H and 5A-5D respectively illustrate cross-sectional and top-down views of forming the resistive memory 14, in accordance with an embodiment. The cross-sectional view in FIG. 4A corresponds to a line 4A-4A′ indicated in FIG. 5A. Like reference numerals are used to refer to identical features in the two sets of figures.

With reference to FIGS. 4A and 5A, and according to an embodiment, the first metal line 102 may be formed by depositing over the substrate 120. The substrate 120 and the first metal line 102 may respectively comprise the materials, structures, and/or other components described above with reference to corresponding parts of FIG. 1B.

The first metal line 102 may comprise electrically conductive materials such as copper, aluminum, silver, gold, platinum, or combination thereof. The first metal line 102 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; electrodeposition; or any other layer deposition process or combination thereof.

Next, referring to FIG. 4B, the first insulating layer 114 may be formed by depositing over the first metal line 102 and the substrate 120. The first insulating layer 114 may comprise the materials described with reference to FIG. 1B and may be deposited using any suitable deposition technique, such as any of the techniques from the list provided in the previous paragraph. In one embodiment, the first insulating layer 114 may be silicon oxide deposited by metal-organic CVD using tetraethyl orthosilicate (TEOS). In another embodiment, the first insulating layer 114 may be silicon nitride deposited by plasma-enhanced CVD using dichlorosilane.

Next, and with reference to FIGS. 4C and 5B, a portion 40 of the first insulating layer 114 may be etched. The portion 40 may be etched sufficiently deep that it reveals an upper surface of the first metal line 102. According to various embodiments, the portion 40 may be etched by etching methods, such as wet etching methods comprising hydrofluoric acid, potassium hydroxide, phosphoric acid, nitric acid, ammonium hydroxide, sulfuric acid, hydrogen peroxide, or dry etching methods such as inductively coupled plasma etching (ICPE), reactive-ion etching (RIE), deep reactive-ion etching (DRIE), electron cyclotron resonance etching (ECRE), ion beam etching (IBE), neutral beam etching (NBE), or any other etching process or combination thereof.

With reference to FIG. 4D, and according to an embodiment, a layer stack comprising the first electrode 104, the metal oxide layers 106, the oxygen reservoir layers 108, the metal layers 116, and the second electrode 110 may be formed.

The first electrode 104 may be deposited over the first electrode 102 and comprise the materials described above with reference to FIG. 1B. The first electrode 104 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal- organic CVD; low-pressure CVD; rapid thermal CVD; electrodeposition; or any other layer deposition process or combination thereof.

Next, the first metal oxide layer 106 may be deposited over the first electrode 104 using any suitable deposition technique from the list provided in the previous paragraph. In one embodiment, PVD technique may be used to deposit the first metal oxide layer 106 comprising hafnium oxide, zirconium oxide, or hafnium zirconium oxide. One or more targets comprising high-purity hafnium (99.99%), high-purity zirconium (99.99%), hafnium dioxide (99.9%), or zirconium dioxide (99.9%) may be introduced into a process chamber. Afterwards, a reactive gas mixture comprising argon and oxygen, at a ratio of 1:10 to 10:1 may be flowed into the process chamber at a rate of 2 to 1000 sccm with a chamber pressure of 0.1-10 mTorr. The argon and oxygen ratio may be tuned to control the quantity of oxygen vacancies in the deposited oxide film. Then a direct current (DC) or radio frequency (RF) power may be applied to the target with controlled power level to achieve a discharge power between 50 W and 1500 W. A plasma may be generated to sputter the target, and the sputtered target material may be deposited over the first electrode 104 to form the metal oxide layer 106 comprising hafnium, zirconium, or oxygen. A substrate temperature may be maintained at a range of room temperature to 400° C.

The metal oxide layer 106 may be annealed after deposition using methods comprising rapid thermal process, furnace annealing, or other suitable annealing method. In one example, the annealing method may be a rapid thermal process carried out between 300° C. and 800° C. for 1 s to 60 s. The thermal treatment may enhance the electronic properties by improving the crystallinity of the deposited layer, reducing defects and dislocations.

In another embodiment, ALD technique may be used for depositing the metal oxide layer 106 comprising hafnium oxide, zirconium oxide, or hafnium zirconium oxide. The process may comprise the sequential introduction of at least one of the hafnium precursor and zirconium precursor and an oxidizing reactant into a process chamber under controlled conditions. A pulse of metal precursors comprising tetrakis(dimethylamino)hafnium (TDMAH), tetrakis(ethylmethylamino)hafnium (TEMAH), tetrakis(diethylamido)hafnium (TDEAH), tris(dimethylamino)cyclopentadienyl hafnium (CpHf(NMe₂)₃), tetrakis(dimethylamido)zirconium (TDMAZ), tetrakis(ethylmethylamido)zirconium (TEMAZ), or tetrakis(diethylamido)zirconium (TDEAZ), or tris(dimethylamino)cyclopentadienyl zirconium (CpZr(NMe₂)₃) may flow into the process chamber at a temperature range of approximately 200° C. to 400° C. and a pressure ranging from 0.1 to 1 Torr. The precursor may adsorb on the substrate surface, forming a self-limited layer. A purge step using an inert gas, such as argon and nitrogen, may be followed to remove excess precursors.

Subsequently, an oxidizing reactant comprising water vapor, oxygen or ozone may be introduced to the chamber. A plasma may be generated using a power source set to a frequency and power level, for example, in the range of 1-20 MHz and 50-1500 W. The oxidizing reactant may react with the adsorbed metal precursors, forming a monolayer of metal oxide comprising hafnium, zirconium, oxygen. Another purge step using an inert gas, such as argon and nitrogen, may be followed to remove excess reactants and by-products. Because each ALD cycle may deposit a sub-monolayer of material, the ALD cycle may be repeated until achieving the desired thickness for the metal oxide layer 106 which may range from 1 nm to 10 nm, according to various embodiments. The composition of the metal oxide film may be controlled by adjusting the composition, duration, and other parameters of the metal precursor pulses and oxidizing reactant pulses.

In some embodiments, the deposited oxides thin film may be annealed comprising rapid thermal process, furnace annealing, or other suitable annealing method. For example, the annealing method may be a rapid thermal process carried out between 300° C. and 800° C. for 1 s to 60 s.

Following the deposition of the first metal oxide layer 106, the first oxygen reservoir layer 108 may be deposited over it. The first oxygen reservoir layer 108 may comprise the materials described with reference to FIG. 1B. The first oxygen reservoir layer 108 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; electrodeposition; or any other layer deposition process or combination thereof.

In one embodiment, PVD technique may be used to deposit the oxygen reservoir layer 108 comprising tungsten oxide. A sputtering target comprising high-purity tungsten metal (99.99%) or tungsten oxide (99.99%) may be introduced into a process chamber. Afterwards, a reactive gas mixture, comprising argon and oxygen may be flowed into the process chamber at a rate of 2 to 1000 sccm with chamber pressure in the range of 0.1-10 mTorr. The argon and oxygen gas mixture ratio in a range from 1:10 to 10:1 may be controlled to obtain desired oxygen vacancy concentration in the tungsten oxide thin film. A direct current (DC) or radio frequency (RF) power may be applied to the target that may generate plasma and initiate the sputtering process. The power level may be controlled to achieve a discharge power between 50 W and 1500 W. The tungsten oxide thin film may be deposited over the metal oxide layer 106 with a temperature ranging from room temperature to 400° C.

The tungsten oxide thin film may be annealed after deposition using methods comprising rapid thermal process, furnace annealing, or other suitable annealing method. In one example, the annealing method may be a rapid thermal process carried out between 300° C. and 800° C. for 1 s to 60 s.

In another embodiment, ALD technique may be used to deposit the oxygen reservoir layer 108 comprising tungsten oxide. The process may comprise a sequential introduction of a tungsten precursor and an oxidizing reactant into a process chamber under controlled conditions. A pulse of tungsten hexafluoride (WF₆) or a metalorganic tungsten precursor such as tungsten hexacarbonyl (W(CO)₆), bis(tert-butylimido)bis(N, N′-diisopropylacetamidinato)tungsten (W(N^{t}Bu)₂(ⁱPrAMD)₂), bis(tert-butylimido)-bis(dimethylamido)tungsten (W(N^{t}Bu)₂(NMe₂)₂), bis(cyclopentadienyl)tungsten dihydride (WH₂Cp₂), bis(isopropylcyclopentadienyl)tungsten dihydride (WH₂(ⁱPrCp)₂) or hexakis(dimethylamido)ditungsten (W₂(NMe₂)₆) may flow into the process chamber at a temperature range of approximately 150° C. to 400° C. at a pressure ranging from 0.1 to 1 Torr. The precursor may adsorb on the substrate surface, forming a monolayer. Subsequently, a purge step using an inert gas, such as argon and nitrogen, may be applied to remove excess precursor.

Afterwards, an oxidizing reactant comprising water vapor, oxygen, or ozone may be introduced to the chamber. A plasma may be generated using a power source set to a frequency and power level, for example, in the range of 1-20 MHz and 50-1500 W. A second purge step using an inert gas, such as argon and nitrogen, may be applied to remove excess reactants and by-products. The ALD cycle may be repeated until achieving the desired thickness for the oxygen reservoir layer 108 which may range from 1 nm to 10 nm, according to various embodiments. The composition of the metal oxide film may be controlled by adjusting the concentration, species, duration, and other parameters of the tungsten precursor and the oxidizing reactant pulses.

In some embodiments, the deposited oxides may be annealed comprising rapid thermal process, furnace annealing, or other suitable annealing method. For example, the annealing process may involve heating the substrate to temperatures ranging from 300° C. to 700° C. for a duration of 30 minutes to several hours, in an environment comprising oxygen or argon.

The sequence of depositing the first metal oxide layer 106 and the first oxygen reservoir layer 108 may be repeated to deposit multiple metal oxide layers 106 and oxygen reservoir layers 108, forming the super-lattice structure 107. In some embodiments, one or more of the oxygen reservoir layers 108 may be substituted with a metal layer 116. This substitution may enhance the device's electrical properties by offering additional pathways for electron conduction and improve thermal stability by enabling more efficient heat dissipation. In one embodiment, as illustrated in FIG. 4D, a second metal oxide layer 106 may be disposed over the first oxygen reservoir layer 108, and a first metal layer 116 may be disposed over the second metal oxide layer 106. Further alternating deposition of the metal oxide layer 106 and the oxygen reservoir layer 108 may be repeated to create more layer stacks. Additional alternating deposition of the metal oxide layer 106 and the metal layer 116 may also be repeated to create additional layer stacks. These interfaces formed by multiple layers may increase the conducting filament formation and rupture points, thereby achieving a broader range of conductance states.

The metal layer 116 may comprise the materials described with reference to FIG. 2A. The metal layer 116 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; electrodeposition; or any other layer deposition process or combination thereof.

In one embodiment, the PVD technique may be used to deposit the metal layer 116 comprising tungsten. A high-purity tungsten metal target (99.99%) may be introduced into the process chamber. Afterwards, an inert gas comprising argon, may be flowed into the chamber at a rate of 10 to 1000 sccm, maintaining a chamber pressure within the range of 0.1 to 10 mTorr. The flow of inert gas facilitates the creation of a consistent plasma environment necessary for effective sputtering. During deposition, a direct current (DC) or radio frequency (RF) power supply may be engaged, applying a power in the range of 50 to 1500 W to generate the plasma that may sputter tungsten atoms from the target onto the substrate. The substrate temperature may be maintained from room temperature to 400° C. to ensure optimal adhesion and film quality.

After deposition, the tungsten layer may be annealed using methods such as rapid thermal process, furnace annealing, or other suitable annealing method. In one example, rapid thermal processing may be executed at temperatures ranging from 300° C. to 900° C. for durations between 10 seconds to 2 minutes, enhancing the film's crystallinity and electrical properties.

In some embodiments, the super-lattice structure 107 comprising metal oxide layers 106, oxygen reservoir layers 108, or metal layers 116, may be formed using an in-situ fabrication method comprising depositing multiple layers within the same process chamber.

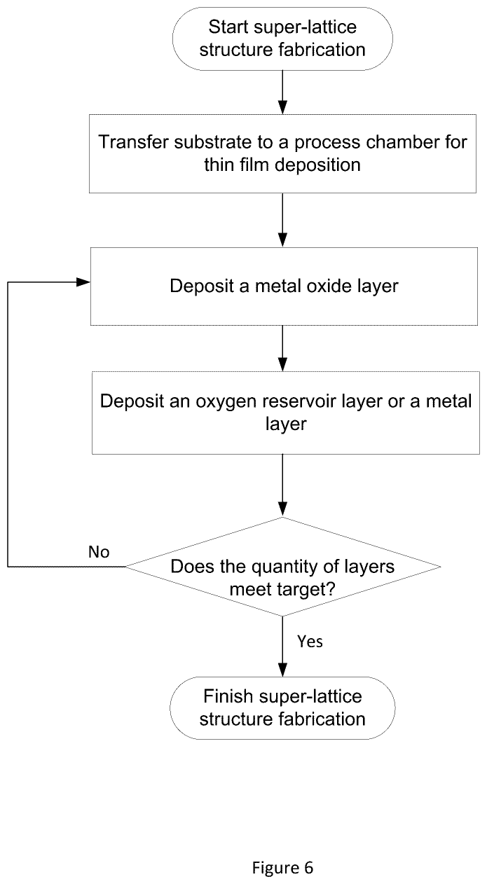

FIG. 6 illustrates a flow chart for an in-situ fabrication method, according to an embodiment. The substrate, prepared for the deposition of the super-lattice structure 107, may be introduced into a process chamber designed for thin film deposition using techniques such as PVD, ALD, or CVD. In one embodiment, the metal oxide layer 106 may be first deposited. Without transferring the substrate to a different chamber, the oxygen reservoir layer 108 or the metal layer 116 may be deposited afterwards. If the quantity of deposited layers does not meet the desired target, additional layers can be deposited in the same chamber by continuing with another metal oxide layer 106, followed by either an oxygen reservoir layer 108 or a metal layer 116. This process may be repeated until the targeted quantity of layers is achieved. While the illustrated process starts with the deposition of metal oxide layer 106, in some embodiments, it may start with the deposition of oxygen reservoir layer 108 or metal layer 116, followed by the deposition of metal oxide layer 106.

In one embodiment, in-situ fabrication may be performed in a process chamber designed for PVD technique. The super-lattice structure 107 may comprise the metal oxide layers 106 comprising hafnium oxide, zirconium oxide, hafnium zirconium oxide, the oxygen reservoir layers 108 comprising tungsten oxide, or the metal layers 116 comprising tungsten metal. A plurality of target materials may be introduced into the process chamber, the target materials comprising hafnium, zirconium, or tungsten metal target with purity of 99.95%-99.99%. Afterwards, the substrate may be transferred into the process chamber with a base pressure at 10⁻⁸-10⁻¹⁰ Torr. A first reactive gas comprising argon and oxygen may be flowed into the process chamber at a rate of 2 to 1000 sccm with chamber pressure in the range of 0.1-10 mTorr. The argon and oxygen ratio in a range from 1:10 to 10:1 may be controlled to obtain desired oxygen vacancy concentration in the deposited oxide thin film. A direct current (DC) or radio frequency (RF) power may be applied to at least one of the hafnium target and zirconium target that may create plasma. The power level may be controlled to achieve a discharge power between 50 W and 1500 W. The plasma may sputter the target and the sputtered materials may be deposited over the substrate, forming the metal oxide layer 106. A substrate temperature of room temperature to 400° C. may be maintained for improved thin film homogeneity and adhesion.

Without breaking vacuum, the process chamber may be evacuated to the base pressure of 10⁻⁸-10⁻¹⁰ Torr to remove the first reactive gas and any residual sputtered materials. The step ensures a clean environment before proceeding to next thin film deposition. Afterwards, a second reactive gas comprising argon or oxygen may be flowed into the process chamber at a rate of 2 to 1000 sccm with chamber pressure in the range of 0.1-10 mTorr. The ratio of argon and oxygen may be controlled to obtain desired thin film characteristics. In one embodiment, the reactive gas may be argon to deposit metallic thin film. In another embodiment, the reactive gas may be a mixture of argon and oxygen to deposit oxide thin film. The argon and oxygen ratio may be controlled between 1:10 to 10:1 to tune the quantity of oxygen vacancy in the deposited oxide thin film. A direct current (DC) or radio frequency (RF) power may be applied to the tungsten target that may create plasma. The power level may be controlled to achieve a discharge power between 50 W and 1500 W. The plasma may sputter the target and the sputtered materials may be deposited over the substrate, forming the oxygen reservoir layer 106 or the metal layer 116. A substrate temperature of room temperature to 400° C. may be maintained for improved adhesion and film quality. The chamber may be evacuated to the base pressure at 10⁻⁸-10⁻¹⁰ Torr to prepare a clean environment before proceeding to the following material layer deposition.

This alternating deposition sequence of the metal oxide layer 106 and the oxygen reservoir layer 108 or the metal layer 116 may be repeated to form multiple layers, ultimately creating the super-lattice structure 107. Utilizing this in-situ fabrication method offers many advantages, including significantly enhanced interface quality due to minimized risk of contamination that often accompanies multiple chamber visits. Additionally, this approach may increase production efficiency by reducing the time typically required to transfer substrates between multiple process chambers.

In some embodiments, the super-lattice structure 107 may be formed using an ex-situ method comprising depositing multiple layers in multiple process chambers. Each of the multiple process chambers may specialize in a deposition technique of ALD, PVD, or CVD. A transfer chamber may be used to transfer the substrate between different process chambers to minimize contamination.

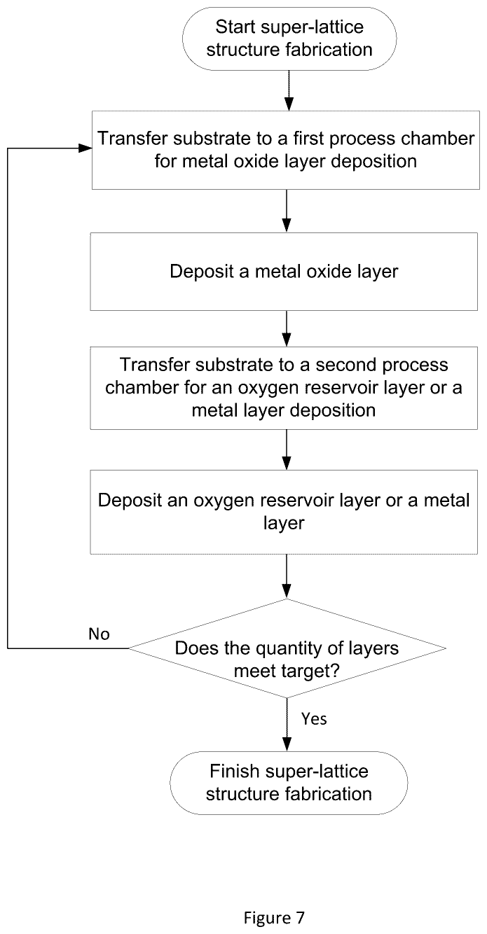

With reference to FIG. 7, according to an embodiment, the substrate may be transferred to a dedicated process chamber such as ALD or PVD designed for the metal oxide layer 106 deposition. Following this, the substrate may be transferred to a transfer chamber, which provides a controlled environment with pressure ranges between 10⁻² and 10⁻⁵ mTorr to minimize contamination during movement between different chambers. Using a load lock, the substrate may be transferred to a dedicated process chamber designed for oxygen reservoir layer or metal layer deposition. If the quantity of deposited layers does not meet the desired target, additional layers may be deposited following the alternating deposition sequence described above. This cycle of deposition may be repeated until the formation of super-lattice structure 107. While the illustrated process starts with the deposition of metal oxide layer 106, in some embodiments, it may start with the deposition of oxygen reservoir layer 108 or metal layer 116, followed by the deposition of metal oxide layer 106.

Periodically, the substrate may be transferred to characterization tools available in separate chambers through the transfer chambers. Characterization tools such as X-ray diffraction (XRD) for crystallinity analysis, scanning electron microscopy (SEM) for surface morphology, ellipsometry for layer thickness measurement, and energy-dispersive X-ray spectroscopy (EDX) for material composition verification may be used to monitor layer characteristics under specified conditions. These steps ensure that each deposited layer meets the quality standards necessary for optimal device performance. The controlled transfer and rigorous monitoring throughout the ex-situ process contribute to the high-quality formation of the super-lattice structure with consistently engineered layers essential for advanced resistive memory devices.

After forming the super-lattice structure 107, the second electrode 110 may be deposited over the oxygen reservoir layer 108, serving as the top electrode. The second electrode 110 completes the stack and acts as an electrical contact with the word line, facilitating the operation of the resistive memory device 12. The second electrode 110 may comprise the materials described with reference to FIG. 1B. The second electrode 110 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal- organic CVD; low-pressure CVD; rapid thermal CVD; electrodeposition; or any other layer deposition process or combination thereof.

Next, and with reference to FIGS. 4E and 5C, the layer stack formed with reference to FIG. 4D may be patterned and etched wherein the etched stack comprises a portion 42. The patterning and etching may be performed by any suitable lithography technique, such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, high-numerical aperture EUV (high-NA EUV), or deep UV (DUV) lithography, in combination with any etching method, such as wet etching methods comprising hydrofluoric acid, potassium hydroxide, phosphoric acid, nitric acid, ammonium hydroxide, sulfuric acid, hydrogen peroxide, and dry etching technique such as inductively coupled plasma etching (ICPE), reactive-ion etching (RIE), deep reactive-ion etching (DRIE), electron cyclotron resonance etching (ECRE), ion beam etching (IBE), neutral beam etching (NBE), or any other etching process or combination thereof. The portion 42 may be etched sufficiently deep that it reveals an upper surface of the first insulating layer 114.

Next, referring to FIG. 4F, the second insulating layer 114′ may be formed by depositing over the second electrode 110 and the first insulating layer 114. The second insulating layer 114′ may comprise the same composition with the first insulating layer 114 as described with reference to FIG. 4B. The second insulating layer 114′ may be deposited using any of the deposition methods described with reference to FIG. 4B for depositing the first insulating layer 114.

Next, and with reference to FIGS. 4G and 5D, a portion 44 of the second insulating layer 114′ may be etched. The portion 44 may be etched sufficiently deep that it reveals an upper surface of the second electrode 110. According to various embodiments, the portion 44 may be etched using any of the etching methods described with reference to FIG. 4C for etching portion 40.

Now referring to FIG. 4H, and according to an embodiment, the second metal line 112 may be formed by depositing over the second electrode 110 and the second insulating layer 114'. The second metal line 112 may comprise the materials, structures, and/or other components described above with reference to corresponding parts of FIG. 1B. The second metal line 112 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; electrodeposition; or any other layer deposition process or combination thereof.

The resistive memory 14 formed by embodiments of the formation steps as illustrated in FIGS. 4A-4H and 5A-5D represents one possible device configuration. The formation steps may be combined or adapted to various other device configurations. For example, the sequential deposition of metal oxide layers 106 and oxygen reservoir layers 108 may be tailored or combined to fabricate other configurations as required by specific device applications. For example, the deposition sequence of the oxygen reservoir layer 108 and the metal oxide layer 106 may be switched. This alternative sequence involves initially depositing an oxygen reservoir layer 108 over the first electrode 104, followed by a metal oxide layer 106, and continuing this alternating order. Switching the sequence may enhance device cycling stability, particularly if the oxygen reservoir layer 108 has a better lattice match with the first electrode 104. A more compatible lattice structure may reduce stress and defects at the interface, mitigating potential points of failure and consequently increasing the durability of the device.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A resistive memory comprising:
a first metal line oriented along a first direction;
a first electrode coupled to the first metal line and disposed over the first metal line;
a first metal oxide layer disposed over the first electrode;
a first oxygen reservoir layer disposed over the first metal oxide layer;
a second metal oxide layer disposed over the first oxygen reservoir layer;
a second oxygen reservoir layer disposed over the second metal oxide layer;
a second electrode disposed over the second oxygen reservoir layer; and
a second metal line coupled to the second electrode and oriented along a second direction disposed over the second electrode, the first and the second electrodes, the first and the second oxygen reservoir layers, and the first and the second metal oxide layers being part of a resistive memory device.

2. The device of claim 1, wherein the second direction is orthogonal to the first direction.

3. The device of claim 1, wherein the first electrode comprises copper, aluminum, tungsten, titanium, titanium nitride, platinum, or gold.

4. The device of claim 1, wherein the first metal oxide layer comprises hafnium oxide, zirconium oxide, or hafnium zirconium oxide, and wherein the first oxygen reservoir layer comprises tungsten oxide.

5. The device of claim 1, wherein the first metal oxide layer comprises a thickness between 1 nm and 10 nm; and wherein the first oxygen reservoir layer comprises a thickness between 1 nm and 10 nm.

6. The device of claim 1, further comprising:
a transistor coupled to the first electrode, the transistor and the resistive memory device being part of a 1T-1R memory cell.

7. A resistive memory comprising:
a first metal line oriented along a first direction;
a first electrode coupled to the first metal line and disposed over the first metal line;
a first metal oxide layer disposed over the first electrode;
a first oxygen reservoir layer disposed over the first metal oxide layer;
a second metal oxide layer disposed over the first oxygen reservoir layer;
a first metal layer disposed over the second metal oxide layer;
a second electrode disposed over the first metal layer; and
a second metal line coupled to the second electrode and oriented along a second direction disposed over the second electrode, the first and the second electrodes, the first and the second metal oxide layers, the first oxygen reservoir layer, and the first metal layer being part of a resistive memory device.

8. The device of claim 7, wherein the second direction is orthogonal to the first direction.

9. The device of claim 7, wherein the first electrode comprises copper, aluminum, tungsten, titanium, titanium nitride, platinum, or gold.

10. The device of claim 7, wherein the first metal oxide layer comprises hafnium oxide, zirconium oxide, or hafnium zirconium oxide, and wherein the first oxygen reservoir layer comprises tungsten oxide, and wherein the first metal layer comprises tungsten, hafnium, zirconium, platinum, copper, or aluminum.

11. The device of claim 7, wherein the first metal oxide layer comprises a thickness between 1 nm and 10 nm; and wherein the first oxygen reservoir layer comprises a thickness between 1 nm and 10 nm.

12. The device of claim 7, further comprising:
a transistor coupled to the first electrode, the transistor and the resistive memory device being part of a 1T-1R memory cell.

13. A method of forming a resistive memory, the method comprising:
forming a first metal line disposed over a substrate, the first metal line oriented along a first direction;
forming a first electrode disposed over the first metal line;
forming a first metal oxide layer disposed over the first electrode;
forming a first oxygen reservoir layer disposed over the first metal oxide layer;
forming a second metal oxide layer disposed over the first oxygen reservoir layer;
forming a second oxygen reservoir layer disposed over the second metal oxide layer;
forming a second electrode disposed over the second oxygen reservoir layer; and
forming a second metal line disposed over the second electrode and oriented along a second direction, wherein the second direction is orthogonal to the first direction.

14. The method of claim 13, wherein forming the first metal oxide layer and the first oxygen reservoir layer comprises performing a plurality of cycles of deposition, one of the plurality of cycles of deposition comprising:
flowing a first precursor gas for a first time duration into a process chamber;
exposing the substrate to the first precursor gas;
purging the process chamber;
flowing a second precursor gas for a second time duration into the process chamber, the second precursor gas comprising argon, ozone or water;
exposing the substrate to the second precursor gas; and
purging the process chamber.

15. The method of claim 14, wherein the first precursor gas comprises tetrakis(dimethylamino)hafnium (TDMAH), tetrakis(ethylmethylamino)hafnium (TEMAH), tetrakis(diethylamido)hafnium (TDEAH), ), tris(dimethylamino)cyclopentadienyl hafnium (CpHf(NMe₂)₃), tetrakis(dimethylamido)zirconium (TDMAZ), tetrakis(ethylmethylamido)zirconium (TEMAZ), tetrakis(diethylamido)zirconium (TDEAZ), tris(dimethylamino)cyclopentadienyl zirconium (CpZr(NMe₂)₃), tungsten hexafluoride (WF₆), tungsten hexacarbonyl (W(CO)₆), bis(tert-butylimido)bis(N, N′-diisopropylacetamidinato)tungsten (W(N^{t}Bu)₂(ⁱPrAMD)₂), bis(tert-butylimido)-bis(dimethylamido)tungsten (W(N^{t}Bu)₂(NMe₂)₂), bis(cyclopentadienyl)tungsten dihydride (WH₂(Cp)₂), bis(isopropylcyclopentadienyl)tungsten dihydride (WH₂(ⁱPrCp)₂) or hexakis(dimethylamido)ditungsten (W₂(NMe₂)₆).

16. The method of claim 13, wherein forming the first metal oxide layer and the first oxygen reservoir layer comprises performing a plurality of cycles of deposition, one of the plurality of cycles of deposition comprising:
providing a first target material within a process chamber, the first target material comprising hafnium or zirconium;
flowing a first reactive gas into the process chamber, the first reactive gas comprising argon or oxygen;
powering an electrode of the process chamber to generate a first plasma;
sputtering the first target material with the first plasma;
depositing the sputtered material onto the substrate to form the metal oxide layer;
providing a second target material within the process chamber after purging the process chamber, the second target material comprising tungsten;
flowing a second reactive gas into the process chamber, the second reactive gas comprising argon or oxygen;
powering the electrode of the process chamber to generate a second plasma;
sputtering the second target material with the second plasma; and
depositing the sputtered material onto the substrate to form the first oxygen reservoir layer.

17. The method of claim 13, wherein the first electrode comprises copper, aluminum, tungsten, platinum, gold, titanium, or titanium nitride.

18. The method of claim 13, wherein the first metal oxide layer comprises hafnium oxide, zirconium oxide, or hafnium zirconium oxide, and wherein the first oxygen reservoir layer comprises tungsten oxide.

19. The method of claim 13, wherein the first metal oxide layer comprises a thickness between 1 nm and 10 nm; and wherein the first oxygen reservoir layer comprises a thickness between 1 nm and 10 nm.

20. The method of claim 13, further comprising:
forming a transistor coupled to the first electrode, the transistor and the resistive memory being part of a 1T-1R memory cell.
